(19) United States
(12) Patent Application Publication
(10) Pub. No.: US 2025/0076390 A1
(43) Pub. Date: Mar. 6, 2025

(54) TESTING APPARATUS FOR POWER MODULE WITH INTEGRATED DC TEST AND WITHSTAND VOLTAGE TEST FUNCTIONS AND TEST METHOD USING THE SAME

(71) Applicants: HYUNDAI MOTOR COMPANY, Seoul (KR); KIA CORPORATION, Seoul (KR)

(72) Inventors: Tae Woo KWANG, Hanam-si (KR); Young Jin SON, Suwon-si (KR)

(21) Appl. No.: 18/434,701

(22) Filed: Feb. 6, 2024

(30) Foreign Application Priority Data
Sep. 4, 2023 (KR) 10-2023-0116754

(51) Int. Cl. G01R 31/3835; G01R 31/26; G01R 31/28

(52) U.S. Cl. CPC G01R 31/3835; G01R 31/2601; G01R 31/2886

(57) ABSTRACT

A testing apparatus for a power module includes a first socket board including a first withstand voltage test pin, a second socket board including a second withstand voltage test pin and a DC test pin, a tester configured to generate a withstand voltage test signal and transmit the withstand voltage test signal to the first withstand voltage test pin and the second withstand voltage test pin, and to generate a DC test signal and transmit the DC test signal to the DC test pin, and a relay closing or opening an electrical connection between the tester and at least one of the first withstand voltage test pin, the second withstand voltage test pin, and the DC test pin.

### CROSS-REFERENCE TO RELATED APPLICATION(S)

This application claims benefit of priority to Korean Patent Application No. 10-2023-0116754, filed on Sep. 4, 2023, in the Korean Intellectual Property Office, the disclosure of which is incorporated herein by reference in its entirety.

### TECHNICAL FIELD

The present disclosure relates to a testing apparatus for a power module with integrated direct current (DC) test and withstand voltage test functions and a test method using the same, and more particularly, to a testing apparatus and test method to implement a process in which DC testing and withstand voltage testing of a power module are integrated.

### BACKGROUND

A power module is a device used to convert direct current power into alternating current power when driving motors of hybrid vehicles, electric vehicles, and the like. Typically, a power module may include a substrate, a power semiconductor device as a switching device bonded to the substrate, a power lead applying power to the power semiconductor device, a signal lead providing a control signal to the power semiconductor device, and the like.

After power modules are manufactured, the power modules may be selected as good or defective products through electrical characteristic inspection. Electrical characteristics testing performed on power modules may generally be performed in an End-Of-Line (EOL) evaluation process, and may include direct current (DC) testing, alternating current (AC) testing, and withstand voltage testing.

In the related art EOL evaluation process, a process for inspecting each electrical characteristic is separated. Accordingly, since both the test process and test equipment are individualized, the cycle time (C/T) of the process increases, and as the footprint of the equipment for the process increases, the overall efficiency of the process may decrease and management may be difficult.

### SUMMARY

An aspect of the present disclosure is to provide a testing apparatus for a power module that may perform both DC testing and withstand voltage testing during electrical characteristics testing, to reduce a cycle time of a test process of inspecting electrical characteristics of the power module and the footprint occupied by the test equipment.

According to an aspect of the present disclosure, a testing apparatus for a power module includes a first socket board including a first withstand voltage test pin; a second socket board including a second withstand voltage test pin and a DC test pin; a tester configured to generate a withstand voltage test signal and transmit the withstand voltage test signal to the first withstand voltage test pin and the second withstand voltage test pin, and to generate a DC test signal and transmit the DC test signal to the DC test pin; and a relay closing or opening an electrical connection between the tester and at least one of the first withstand voltage test pin, the second withstand voltage test pin, and the DC test pin.

The power module may include a lower substrate, an upper substrate disposed in parallel with the lower substrate, and a semiconductor device disposed between the lower substrate and the upper substrate, and the first socket board may include an upper socket board disposed to face the upper substrate and a lower socket board disposed to face the lower substrate.

The first withstand voltage test pin of the upper socket board may contact at least a portion of the upper substrate, and the first withstand voltage test pin of the lower socket board may contact at least a portion of the lower substrate.

The power module may further include a power lead and a signal lead, at least a portion of which is exposed to an outside of a housing of the power module, and the second socket board may be provided such that the second withstand voltage test pin and the DC test pin are in contact with the power lead and the signal lead, respectively.

The second socket board may be comprised of a socket board for a power lead, corresponding to the power lead, and a socket board for a signal lead, corresponding to the signal lead. The socket board for a power lead and the socket board for a signal lead may be disposed on both sides of the lower socket board.

The second withstand voltage test pin and the DC test pin of the socket board for a power lead may contact at least a portion of the power lead, and the second withstand voltage test pin and the DC test pin of the socket board for a signal lead may contact at least a portion of the signal lead.

The first socket board may further include a first plate, and the first withstand voltage test pin may be located facing the power module, on the first plate.

The second socket board may further include a second plate, the DC test pin may be comprised of a plurality and may be located facing the power module, on the second plate, and the second withstand voltage test pin may be located facing the power module, between the plurality of DC test pins.

The testing apparatus may be operable in a DC test mode or a withstand voltage test mode, and the relay may switch the testing apparatus to the DC test mode or the withstand voltage test mode by controlling an electrical connection between the DC test pin and the tester and an electrical connection between the first and second withstand voltage test pins and the tester.

The relay may electrically connect the tester to the DC test pin in the DC test mode.

The relay may electrically connect the tester to the first withstand voltage test pin and the second withstand voltage test pin in the withstand voltage test mode.

The relay may include a plurality of relays connected between the first withstand voltage test pin and the tester, between the second withstand voltage test pin and the tester, and between the DC test pin and the tester.

In the DC test mode, the plurality of relays connected to the DC test pin may be closed, and the plurality of relays connected to the first withstand voltage test pin and the second withstand voltage test pin may be open.

In the withstand voltage test mode, the plurality of relays connected to the first withstand voltage test pin and the second withstand voltage test pin may be closed, and the plurality of relays connected to the DC test pin may be open.

The plurality of relays may include a cylinder relay.

According to another aspect of the present disclosure, a method of testing electrical characteristics of a power module includes mounting the power module on a testing apparatus; operating the testing apparatus in a DC test mode and performing a DC test of the power module; and operating the testing apparatus in a withstand voltage test mode and performing a withstand voltage test of the power module. The testing apparatus includes a first socket board including a first withstand voltage test pin; a second socket board including a second withstand voltage test pin and a DC test pin; a tester generating a withstand voltage test signal and a DC test signal; and a relay switching an operating mode of the testing apparatus to the DC test mode or the withstand voltage test mode. In the mounting of the power module on the testing apparatus, the power module may be configured to contact the first withstand voltage test pin, the second withstand voltage test pin, and the DC test pin.

In the performing a DC test of the power module, the relay may be configured to electrically connect the tester to the DC test pin.

In the performing a withstand voltage test of the power module, the relay may be configured to electrically connect the tester to the first withstand voltage test pin and the second withstand voltage test pin.

The relay may include a plurality of relays connected between the first withstand voltage test pin and the tester, between the second withstand voltage test pin and the tester, and between the DC test pin and the tester.

In the DC test mode, the plurality of relays connected to the DC test pin may be closed, and the plurality of relays connected to the first withstand voltage test pin and the second withstand voltage test pin may be open. In the withstand voltage test mode, the plurality of relays connected to the first withstand voltage test pin and the second withstand voltage test pin may be closed, and the plurality of relays connected to the DC test pin may be open.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a perspective view showing an example of a power module.

FIG. 2 is a cross-sectional view showing an example of a power module.

FIG. 3 is a diagram illustrating an example of a power module and a testing apparatus for a power module.

FIG. 4 is a diagram illustrating an example of a first socket board of a testing apparatus for a power module.

FIG. 5 is a diagram illustrating an example of a second socket board of a testing apparatus for a power module.

FIG. 6 is a diagram illustrating example positions between a power module, a first socket board, and a second socket board when performing testing using a testing apparatus for a power module.

FIG. 7 is a diagram illustrating an example of an electrical connection path for a withstand voltage test of a power module in a testing apparatus for a power module.

FIG. 8A is a diagram illustrating an example of a DC test circuit of a testing apparatus for a power module.

FIG. 8B is a diagram illustrating an example of a withstand voltage test circuit of a testing apparatus for a power module.

### DETAILED DESCRIPTION

Since the present disclosure may make various changes and have various embodiments, some embodiments are illustrated in the drawings and described in detail. However, this is not intended to limit the present disclosure to the embodiments, and should be understood to include all modifications, equivalents, and substitutes included in the spirit and scope of the present disclosure.

Terms such as first and second may be used to describe various components, but the components should not be limited by the terms. These terms are only used for distinguishing one component from another. For example, a first element may be termed a second element, and similarly, a second element may be termed a first element, without departing from the scope of the present disclosure. The term ‘and/or’ includes a combination of a plurality of related recited items or any one of a plurality of related recited items.

Terms used in this application are only used to describe embodiments, and are not intended to limit the present disclosure. Singular expressions include plural expressions unless the context clearly dictates otherwise. In this application, the terms “include,” “have” and the like are intended to designate that there is a feature, number, step, operation, component, part, or combination thereof described in the specification, but it should be understood that it does not preclude the possibility of the presence or addition of one or more other features, numbers, steps, operations, components, parts, or combinations thereof.

Unless defined otherwise, all terms used herein, including technical or scientific terms, have the same meaning as commonly understood by one of ordinary skill in the art to which the present disclosure belongs. Terms such as those defined in commonly used dictionaries should be interpreted as having a meaning consistent with the meaning in the context of the related art, and unless expressly defined in this application, it is not to be construed in an ideal or overly formal sense.

Hereinafter, with reference to the accompanying drawings, embodiments of the present disclosure will be described in more detail.

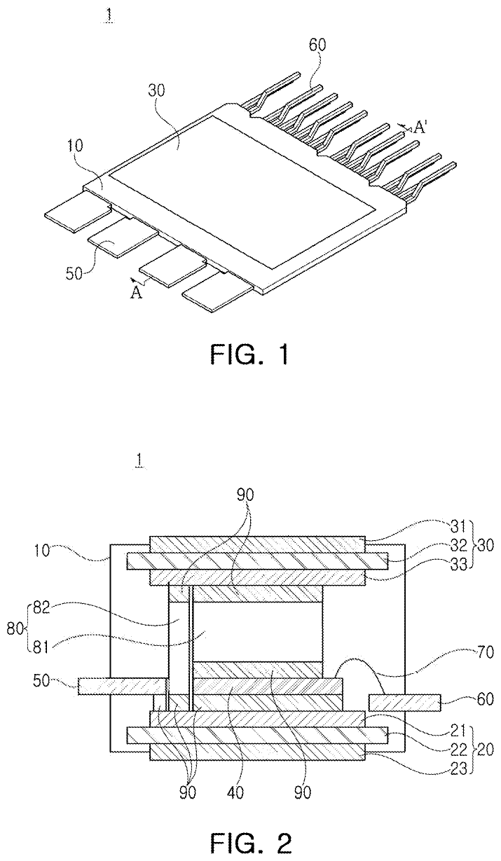

FIG. 1 is a perspective view of a power module 1. FIG. 2 is a cross-sectional view of the power module 1.

FIG. 2 is a diagram illustrating a cross section taken along line A-A′ of the power module 1 illustrated in FIG. 1.

Referring to FIGS. 1 and 2, the power module 1 may include a housing 10, a lower substrate 20, an upper substrate 30, a semiconductor device 40, a power lead 50, a signal lead 60, a wire 70, a spacer 80, and a solder member 90.

The housing 10 may accommodate at least some of the components constituting the power module 1 therein. For example, the housing 10 may surround components disposed between the lower substrate 20 and the upper substrate 30, such that at least portions of the lower substrate 20, the upper substrate 30, the power lead 50, and the signal lead 60 are exposed to the outside of the housing 10. The housing 10 may be a molding part formed of an insulating material that molds the components constituting the power module 1.

The lower substrate 20 may include an insulating layer 22 and metal layers 21 and 23 disposed on both sides of the insulating layer 22. The metal layers 21 and 23 may include a first metal layer 21 bonded to the upper surface of the insulating layer 22 and a second metal layer 23 bonded to the lower surface of the insulating layer 22. The first metal layer 21 of the lower substrate 20 may be in electrical contact with the lower surface of the semiconductor device 40. At least a portion (e.g., a lower surface) of the second metal layer 23 of the lower substrate 20 may be exposed by being located outside the housing 10. In some examples, the second metal layer 23 of the lower substrate 20 may be in contact with a cooling channel for cooling the power module 1.

The upper substrate 30 may include an insulating layer 32 and metal layers 31 and 33 disposed on both sides of the insulating layer 32. The metal layers 31 and 33 may include a first metal layer 33 bonded to the lower surface of the insulating layer 32 and a second metal layer 31 bonded to the upper surface of the insulating layer 32. The first metal layer 33 of the upper substrate 30 may be in electrical contact with the upper surface of the semiconductor device 40 through a first spacer 81. At least a portion (e.g., an upper surface) of the second metal layer 31 of the upper substrate 30 may be exposed by being located outside the housing 10. In some examples, the second metal layer 31 of the upper substrate 30 may be in contact with a cooling channel for cooling the power module 1.

The lower substrate 20 and the upper substrate 30 may be Double Bonded Copper (DBC) substrates. For example, the upper substrate 30 and the lower substrate 20 may have the insulating layers 22 and 32 formed of a ceramic material and the metal layers 21, 23, 31 and 33 formed of a copper material, but are not limited thereto.

The lower substrate 20 and the upper substrate 30 may be electrically connected through the spacer 80. For example, the first metal layer 21 of the lower substrate 20 and the first metal layer 33 of the upper substrate 30 may be electrically connected through a second spacer 82. A portion of the first metal layer 21 of the lower substrate 20 electrically connected to the lower surface of the semiconductor device 40 may be configured to be electrically insulated from a portion of the first metal layer 21 of the lower substrate 20 electrically connected to the first metal layer 33 of the upper substrate 30 through the second spacer 82.

The semiconductor device (or a semiconductor chip) 40 may be disposed between the lower substrate 20 and the upper substrate 30. For example, the semiconductor device 40 may be bonded to the first metal layer 21 of the lower substrate 20 and positioned between the lower substrate 20 and the upper substrate 30. The semiconductor device 40 may be electrically connected to the upper substrate 30 and the lower substrate 20. For example, the semiconductor device 40 may have power terminals formed on the upper and lower surfaces respectively through which current for power conversion is input and output. The power terminal formed on the lower surface may be electrically connected to the lower substrate 20, and the power terminal formed on the upper surface may be electrically connected to the upper substrate 30. The semiconductor device 40 may be comprised of an insulated gate bipolar transistor (IGBT) and a diode, but is not limited thereto.

The lower surface of the semiconductor device 40 may be bonded to the first metal layer 21 of the lower substrate 20 through the solder member 90. The upper surface of the semiconductor device 40 may be bonded to the first spacer 81 through the solder member 90. For example, the semiconductor device 40 may be electrically connected to the first metal layer 33 of the upper substrate 30 through the first spacer 81. The semiconductor device 40 may be electrically connected to the signal lead 60 through the wire 70.

The power lead 50 is connected to the semiconductor device 40 and may transmit and receive high-voltage current. The power lead 50 may be electrically connected to the semiconductor device 40, and may be comprised of a plurality of power leads. At least a portion of the power lead 50 may be electrically bonded to the first metal layer 21 of the lower substrate 20 through the solder member 90. For example, the power lead 50 may be bonded to the upper surface of the first metal layer 21 of the lower substrate 20 along with the semiconductor device 40. A portion of the power lead 50 may be exposed to the outside of the housing 10 to transmit and receive power to and from the outside of the power module 1. The power lead 50 may extend from the inside of the housing 10 toward the outside of the housing 10 such that at least a portion is exposed to the outside of the housing 10.

The signal lead 60 may receive a control signal for controlling the semiconductor device 40 from the outside of the power module 1, and may be comprised of a plurality of signal leads. The signal lead 60 may extend from the inside of the housing 10 toward the outside of the housing 10 such that at least a portion is exposed to the outside of the housing 10. The signal lead 60 may be electrically connected to the semiconductor device 40 through the wire 70.

The spacer 80 may include the first spacer 81 disposed between the upper substrate 30 and the semiconductor device 40 and the second spacer 82 disposed between the upper substrate 30 and the lower substrate 20.

The first spacer 81 has an upper surface thereof bonded to the first metal layer 33 of the upper substrate 30 and a lower surface thereof bonded to the semiconductor device 40, thereby forming an electrical connection between the upper substrate 30 and the semiconductor device 40. For example, the upper and lower surfaces of the first spacer 81 may electrically and physically contact the first metal layer 33 of the upper substrate 30 and the upper surface of the semiconductor device 40 through the solder member 90, respectively.

In the case of the second spacer 82, an upper surface may be bonded to the first metal layer 33 of the upper substrate 30, and a lower surface may be bonded to the first metal layer 21 of the lower substrate 20, thereby forming an electrical connection between the upper substrate 30 and the lower substrate 20. For example, the upper and lower surfaces of the second spacer 82 may electrically and physically contact the first metal layer 33 of the upper substrate 30 (e.g., the lower surface of the first metal layer 33) and the first metal layer 21 of the lower substrate 20 (e.g., the upper surface of the first metal layer 21) through the solder member 90, respectively.

In some implementations, as illustrated in FIGS. 1 and 2, the power module 1 can be a double-sided cooling (DSC) power module configured to have the semiconductor device 40 disposed between the upper substrate 30 and the lower substrate 20. However, the structure of the power module 1 is not limited to the illustrated embodiment, and may be modified in various manners within the range of implementing the structure in which the semiconductor device 40 is disposed between the upper and lower substrates 20 and heat generated from the semiconductor device 40 is cooled by a cooler installed on the outside of the two substrates.

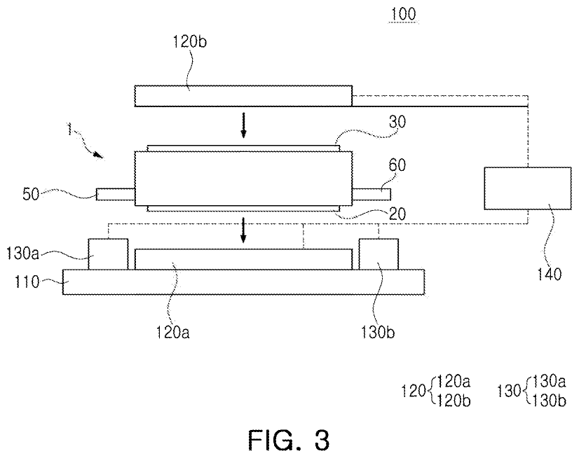

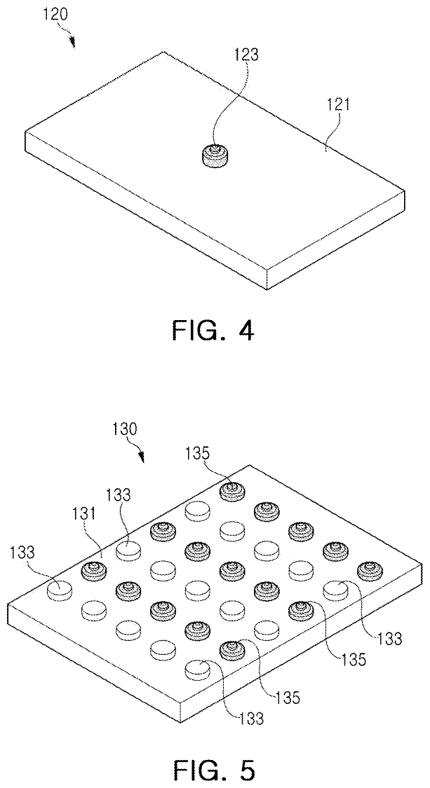

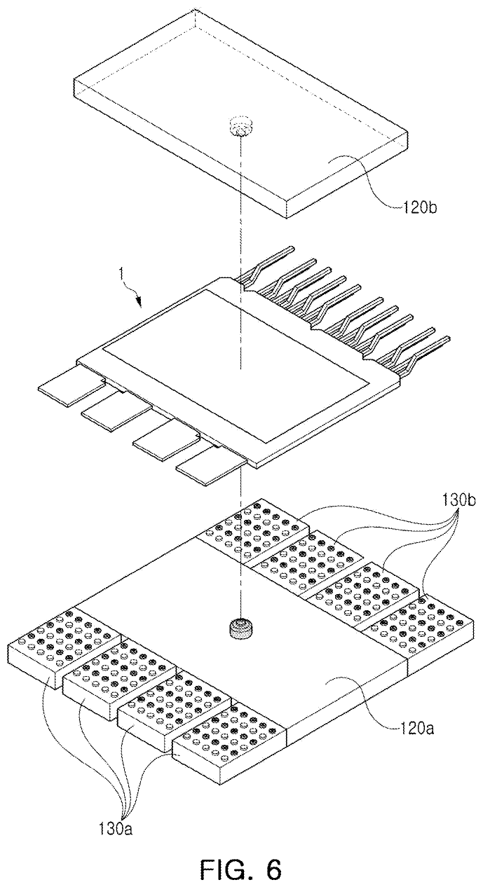

FIG. 3 is a diagram schematically illustrating the power module 1 and a testing apparatus for a power module 100. FIG. 4 is a diagram illustrating a first socket board 120 of the testing apparatus for a power module 100. FIG. 5 is a diagram illustrating a second socket board 130 of the testing apparatus for a power module 100. FIG. 6 is a diagram illustrating the positional relationship between the power module 1, the first socket board 120, and the second socket board 130 when inspected using the testing apparatus for a power module 100.

FIG. 3 is a diagram schematically illustrating an operation in which the power module 1 is mounted on the testing apparatus for a power module 100 for inspection of the power module 1. FIG. 4 is a diagram illustrating a detailed shape of the first socket board 120 illustrated in FIG. 3. FIG. 5 is a diagram illustrating a detailed shape of the second socket board 130 illustrated in FIG. 3. FIG. 6 is a diagram illustrating the positional relationship between the power module 1, the first socket board 120, and the second socket board 130 when the power module 1 is mounted on the testing apparatus for a power module 100.

In some implementations, referring to FIGS. 3 to 6, the testing apparatus for a power module 100 may contact the power module 1 while covering at least a portion of the power module 1 from the top and bottom. The testing apparatus for a power module 100 is configured to perform both a DC test and a withstand voltage test for the power module 1. For example, the power module 1 may perform a DC test and a withstand voltage test through the socket boards 120 and 130 included in the testing apparatus for a power module 100 together, without a transfer process while the power module is seated or mounted on the testing apparatus for a power module 100.

The testing apparatus for a power module 100 may include a base plate 110, the first socket board 120, the second socket board 130, a relay 140, and a tester 150.

The first socket board 120 and the second socket board 130 may be seated on one surface of the base plate 110. For example, the base plate 110 may support the first socket board 120 and the second socket board 130. In some examples, the base plate 110 may be disposed on an upper portion of a test head, and in this case, the test head may be electrically connected to the first socket board 120, the second socket board 130, and the relay 140, generate a test control signal and provide the test control signal to the tester 150, and may generate a relay control signal and provide the relay control signal to the relay 140. According to various embodiments, the base plate 110 may be a portion of the test head.

The first socket board 120 may be a test board for testing the withstand voltage of the power module 1. The first socket board 120 may include a first plate 121 and a first withstand voltage test pin 123 disposed in a partial area of the first plate 121. For example, the first withstand voltage test pin 123 may be disposed in the central portion of one side of the first plate 121. The first withstand voltage test pin 123 may include a pogo pin. The location and number of the first withstand voltage test pins 123 are not limited to the illustrated embodiment.

The first socket board 120 is configured to be electrically connected to the power module 1 through the first withstand voltage test pin 123. For example, as the first withstand voltage test pin 123 contacts the power module 1, an electrical connection may be formed between the power module 1, the first socket board 120, and the tester 150.

The first withstand voltage test pin 123 of the first socket board 120 receives a test signal (e.g., an electrical signal for a withstand voltage test) from the tester 150 and is connected to the power module 1 to transmit the withstand voltage test signal to the power module 1. The first withstand voltage test pin 123 may be electrically connected to at least a portion of the plurality of relays included in the relay 140. The first withstand voltage test pin 123 of the first socket board 120 may be electrically connected to or disconnected from the tester 150 based on the switching operation of the relay 140.

The first socket board 120 may be comprised of two pieces to contact the upper and lower portions of the power module 1, respectively. For example, the first socket board 120 may include a lower socket board 120a and an upper socket board 120b having the same shape. In the testing apparatus for a power module 100, the lower socket board 120a and the upper socket board 120b may be installed such that respective first withstand voltage test pins 123 face the power module 1.

The lower socket board 120a may be disposed on the base plate 110 such that the first withstand voltage test pin 123 faces the power module 1, and the upper socket board 120b may be disposed on an upper portion of the power module 1, such that the first withstand voltage test pin 123 faces the power module 1 in a state in which the power module 1 is mounted on the testing apparatus 100.

For example, when inspecting the power module 1, the first withstand voltage test pin 123 of the lower socket board 120a is disposed to face the lower substrate 20 of the power module 1 and may contact the lower substrate 20, and the first withstand voltage test pin 123 of the upper socket board 120b is disposed to face the upper substrate 30 of the power module 1 and may contact the upper substrate 30.

The first plate 121 of the first socket board 120 may include a heat source that may apply heat to the power module 1 to inspect the power module 1 under high temperature conditions. For example, the first socket board 120 may be a heating block with a heating wire or heater disposed inside.

The second socket board 130 may be a test board for withstand voltage testing and DC testing of the power module 1. The second socket board 130 may include a second plate 131, DC test pins 133 disposed on portions of the second plate 131, and second withstand voltage test pins 135 disposed between the DC test pins 133. The DC test pin 133 and the second withstand voltage test pin 135 may be disposed alternately.

For example, the plurality of DC test pins 133 may be formed over the entire area of one surface of the second plate 131, and the plurality of second withstand voltage test pins 135 may be formed to be located between the plurality of DC test pins 133. The DC test pin 133 and the second withstand voltage test pin 135 may include a pogo pin. The positions and numbers of the DC test pins 133 and the second withstand voltage test pins 135 are not limited to the illustrated embodiment.

The second socket board 130 is configured to be electrically connected to the power module 1 through the DC test pin 133 and the second withstand voltage test pin 135. For example, as the DC test pin 133 and the second withstand voltage test pin 135 are in contact with the power module 1, an electrical connection may be formed between the power module 1, the second socket board 130, and the tester 150.

The DC test pin 133 and the second withstand voltage test pin 135 of the second socket board 130 may receive a test signal (e.g., an electrical signal for a withstand voltage test or an electrical signal for a DC test) from the tester 150, and may be connected to the power module 1 and transmit the withstand voltage test signal or DC test signal to the power module 1. The respective DC test pins 133 and the respective second withstand voltage test pins 135 may be electrically connected to at least portions of the plurality of relays included in the relay 140.

The DC test pins 133 and the second withstand voltage test pins 135 may respectively be electrically connected to a plurality of relays in parallel. The respective DC test pins 133 and the respective second withstand voltage test pins 135 of the second socket board 130 may be electrically connected to or disconnected from the tester 150 based on the switching operation of the relay 140.

The DC test pin 133 and the second withstand voltage test pin 135 of the second socket board 130 may be selectively electrically connected to the tester 150 by the relay 140. For example, when performing a DC test on the power module 1, the DC test pin 133 of the second socket board 130 is electrically connected to the tester 150 to transmit an electrical signal for a DC test on the power module 1 to the power module 1, and the second withstand voltage test pin 135 is not electrically connected to the tester 150.

In some examples, when performing a withstand voltage test on the power module 1, the second withstand voltage test pin 135 of the second socket board 130 is electrically connected to the tester 150 to transmit an electrical signal for a withstand voltage test to the power module 1, and the DC test pin 133 is not electrically connected to the tester 150.

The second socket board 130 may be configured to contact the power lead 50 and the signal lead 60 of the power module 1, respectively. For example, the second socket board 130 may be disposed in a position corresponding to the power lead 50 and the signal lead 60, and may be comprised of a plurality of second socket boards to contact the power lead 50 and the signal lead 60. The second socket board 130 may be disposed on the base plate 110, to be located on both sides of the lower socket board 120a in the short side direction to correspond to the positions of the power lead 50 and the signal lead 60. For example, the second socket board 130 may include a socket board 130a for a power lead corresponding to the power lead 50, and a socket board 130b for a signal lead corresponding to the signal lead 60. For example, in a state in which the power module 1 is mounted on the testing apparatus 100 to inspect the power module 1, at least portions of the plurality of DC test pins 133 and the plurality of second withstand voltage test pins 135 of the second socket board 130 may contact the power lead 50 and the signal lead 60 of the power module 1. However, the location and/or number of the second socket boards 130 are not limited to the illustrated embodiment.

The socket board 130a for a power lead may be configured such that a plurality of power leads 50 respectively contact the DC test pins 133 and the second withstand voltage test pins 135 when the power module 1 is seated or mounted on the testing apparatus for a power module 100. For example, the DC test pins 133 and the second withstand voltage test pins 135 may be disposed in a position in which a plurality of power leads 50 are in contact with the DC test pins 133 and the second withstand voltage test pins 135 at the same time when the power module 1 is seated in the testing apparatus for a power module 100.

The socket board 130b for a signal lead may be configured such that the plurality of signal leads 60 respectively contact the DC test pin 133 and the second withstand voltage test pin 135, when the power module 1 is seated or mounted on the testing apparatus for a power module 100. For example, the DC test pin 133 and the second withstand voltage test pin 135 may be disposed in a position in which the plurality of signal leads 60 are respectively in contact with the DC test pins 133 and the second withstand voltage test pins 135 at the same time when the power module 1 is seated in the testing apparatus for a power module 100.

The relay 140 may switch the operating mode of the testing apparatus for a power module 100 according to the item (or electrical characteristics) for evaluating the power module 1. For example, the relay 140 controls the electrical connection between the tester 150 and the test pins (withstand voltage test pins 123, 135 and DC test pins 133) through a switching operation, thereby switching the operating mode of the testing apparatus for a power module 100 to a withstand voltage test mode and a DC test mode. The relay 140 may include a cylinder relay, through which the influence of electrical noise may be reduced. However, the type of relay 140 is not limited to the above-described examples. According to various embodiments, the relay 140 may be referred to as a switch unit.

The relay 140 may be electrically connected to the socket boards 120 and 130 and the tester 150. The relay 140 may be configured to include a plurality of relays, and the plurality of relays are connected between a plurality of test pins 123, 133, 135 formed on the socket boards 120 and 130 and the tester 150, and are configured to partially connect or block the electrical path between the plurality of test pins 123, 133, and 135 and the tester 150. For example, portions of the plurality of relays are connected between the first withstand voltage test pin 123 of the first socket board 120 and the tester 150 to control (block or allow) the electrical connection therebetween, another portion thereof may be connected between the second withstand voltage test pin 135 of the second socket board 130 and the tester 150 to control (block or allow) the electrical connection therebetween, and still others thereof may be connected between the DC test pin 133 of the second socket board 130 and the tester 150 to control (block or allow) the electrical connection therebetween.

The connection between the plurality of relays included in the relay 140 and the test pins 123, 133, and 135 may be implemented in various manners. For example, the first withstand voltage test pin 123 and the second withstand voltage test pin 135 may be connected to the tester 150 using one relay, or may respectively be connected to the tester 150 using a separate relay. In addition, the plurality of DC test pins 133 are divided into a plurality of groups, and pins included in one group are connected to the tester 150 using one relay, or a plurality of DC test pins 133 may respectively be connected to the tester 150 using separate relays. However, the above is illustrative, and electrical connections between the withstand voltage test pins 123 and 135 and the tester 150 and between the DC test pin 133 and the tester 150, and locations thereof may be provided in various manners using the relay 140 within the range of selective control.

The relay 140 is configured such that the relay connected to the withstand voltage test pins 123 and 135 is open (off state) and the relay connected to the DC test pin 133 is closed (on state) in DC test mode, and thus, the DC test pin 133 is conducted such that the electrical signal for the DC test generated in the tester 150 may be transmitted to the power module 1. In addition, the relay 140 is configured such that the relay connected to the DC test pin 133 is open (off state) and the relay connected to the withstand voltage test pins 123 and 135 is closed (on state) in the withstand voltage test mode, and thus, the withstand voltage test pins 123 and 135 are conducted such that the electrical signal for the withstand voltage test generated in the tester 150 may be transmitted to the power module 1.

The tester 150 may generate a test signal (or electrical signal) to test the electrical characteristics of the power module 1 and transmit the test signal to the power module 1. The tester 150 may generate an electrical signal for a DC test of the power module 1 and an electrical signal for a withstand voltage test. The DC test may be a test to evaluate whether the semiconductor device 40 in the power module 1 operates correctly, by applying a preset voltage to the power module 1 to measure DC characteristics such as open/short, input current, output voltage, power current, and the like. The withstand voltage test may be a test that evaluates the electrical insulation status by applying a high voltage to the power module 1 and checking whether the leakage current is a certain level or less. However, the test method is not limited to the above examples.

In some examples, the tester 150 may include a DC tester that generates a test signal for performing a DC test and a withstand voltage tester that generates a test signal for a withstand test. According to various embodiments, the tester 150 may be included in a test head.

The tester 150 may check whether the power module 1 is in normal contact with the withstand voltage test pins 123 and 135 and the DC test pin 133 while supplying current or voltage, for example, whether the power module 1 is properly connected to the socket boards 120 and 130.

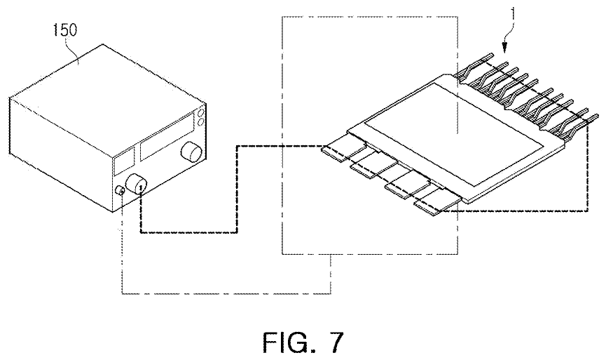

FIG. 7 is a diagram illustrating an electrical connection path for a withstand voltage test of the power module 1 in the testing apparatus for a power module 100.

In describing FIG. 7, reference is also made to FIGS. 3 to 6 described above.

Referring to FIG. 7, in the case of the power module 1, the upper substrate 30 and the lower substrate 20 are electrically connected to the tester 150 through a common node, and the signal lead 60 and the power lead 50 are electrically connected to the tester 150 through a common node, thereby performing a withstand voltage test. For example, the tester 150 illustrated in FIG. 7 may be referred to as a withstand voltage tester (or withstand voltage tester) for performing a withstand voltage test.

The upper substrate 30 and the lower substrate 20 of the power module 1 may be electrically connected to the tester 150 through the first withstand voltage test pins 123 of the upper socket board 120b and the lower socket board 120a, and the power lead 50 and the signal lead 60 of the power module 1 may be electrically connected to the tester 150 through the second withstand voltage test pins 135 of the second socket board 130.

The tester 150 may apply a high voltage to the power module 1 to evaluate the insulation state and resistance level to voltage of the power module 1. For example, the withstand voltage test may be performed by applying a high voltage alternating current (AC) voltage waveform of about 3300 V to the power module 1. By using the AC waveform, the withstand voltage for both + and − directions may be evaluated. However, the withstand voltage test method is not limited to the above examples.

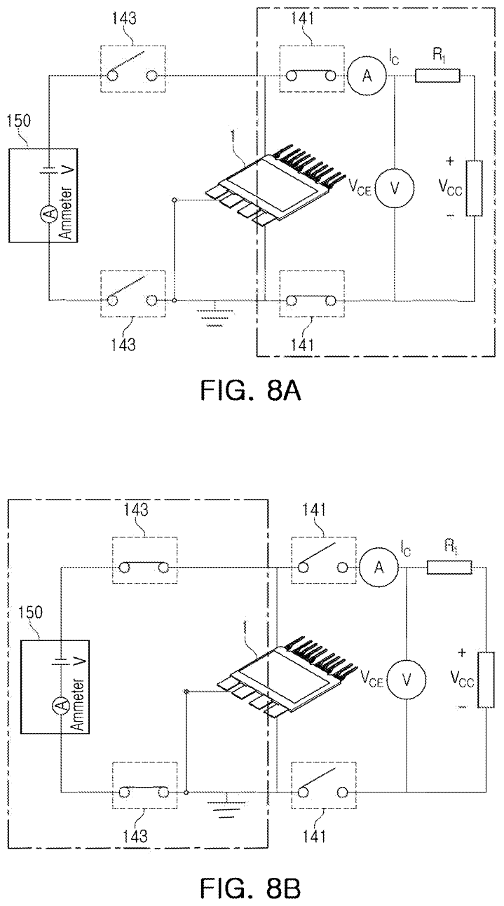

FIG. 8A is a diagram illustrating a DC test circuit of the testing apparatus for a power module 100. FIG. 8B is a diagram illustrating a circuit for a withstand voltage test of the testing apparatus for a power module 100.

FIGS. 8A and 8B are diagrams illustrating circuit connections for a DC test and a withstand voltage test using the testing apparatus for a power module 100.

FIG. 8A illustrates a circuit connection state when the testing apparatus for a power module 100 is in a DC test mode for performing a DC test on the power module 1, and FIG. 8B illustrates a circuit connection status when the testing apparatus for a power module 100 is in a withstand voltage test mode to perform a withstand voltage test on the power module 1. In describing FIGS. 8A and 8B, FIGS. 3 to 7 described above are referred together.

Referring to FIGS. 8A and 8B, the testing apparatus for a power module 100 operates such that the DC test circuit is configured as a closed loop in DC test mode and the withstand voltage test circuit is opened, and the withstand voltage test circuit is configured as a closed loop in the withstand voltage test mode and the DC test circuit is opened.

As illustrated in FIG. 8A, when the testing apparatus for a power module 100 is in DC test mode, the cylinder relay 141 connected to the DC test pin 133 is closed, and the cylinder relay 143 connected to the withstand voltage test pins 123 and 135 is opened, and thus, the DC test circuit is formed as a closed circuit. Accordingly, only the DC test pin 133 is conducted, and the withstand voltage test pins 123 and 135 are not conducted. The DC test signal generated by the tester 150 may be applied to the power module 1 (in detail, the power lead 50 and the signal lead 60) through the DC test pin 133.

As illustrated in FIG. 8B, when the testing apparatus for a power module 100 is in the withstand voltage test mode, the cylinder relay 141 connected to the DC test pin 133 is open, and the cylinder relay 143 connected to the withstand voltage test pins 123 and 135 is closed, such that the withstand voltage test circuit forms a closed circuit. Accordingly, only the withstand voltage test pins 123 and 135 are conducted, and the DC test pin 133 is not conducted, and the withstand voltage test signal generated in the tester 150 may be applied to the power module 1 (in detail, the upper substrate 30, the lower substrate 20, the power lead 50, and the signal lead 60) through the withstand voltage test pins 123 and 135.

Below, a method of testing electrical characteristics of the power module 1 using the testing apparatus for a power module 100 will be described.

First, to test the power module 1, the power module 1 is mounted on the testing apparatus for a power module 100. With the power module 1 mounted on the testing apparatus for a power module 100, the power module 1 may be disposed on the upper socket board 120b and the lower socket board 120a. In addition, when mounted on the testing apparatus for a power module 100, the power module 1 may be disposed such that the upper substrate 30 and the lower substrate 20 contact the first withstand voltage test pin 123 of the first socket board 120, and the power lead 50 and the signal lead 60 are in contact with the second withstand voltage test pin 135 and the DC test pin 133 of the second socket board 130.

After the power module 1 is mounted, a small amount of current may be applied to check whether the power module 1 is electrically connected to the first socket board 120 and the second socket board 130.

After checking the installation and electrical connection status of the power module 1, the cylinder relay 143 connected to the withstand voltage test pins 123 and 135 is open, and the cylinder relay 141 connected to the DC test pin 133 is closed, thereby performing a DC test on the power module 1.

After the DC test is completed, the cylinder relay 141 connected to the DC test pin 133 is opened, and the cylinder relay 143 connected to the withstand voltage test pins 123 and 135 is closed, to perform a withstand voltage test on the power module 1.

For example, according to the testing apparatus for a power module 100, the DC test and the withstand voltage test for the power module 1 are performed in one equipment or process, and therefore, process and facility costs may be reduced as separate processes and facilities are not required. Since there is no need to transport the power module 1 between the DC test and the withstand voltage test, the process may be simplified and mass production may be improved.

As set forth above, the cycle time of a test process and the footprint occupied by the test equipment may be reduced by performing a DC test and a withstand voltage test for the power module in one device.

In addition, the DC test and the withstand voltage test are integrated and performed in one process, thereby reducing equipment costs and increasing mass productivity of products.

While example embodiments have been illustrated and described above, it will be apparent to those skilled in the art that modifications and variations could be made without departing from the scope of the present disclosure as defined by the appended claims.

What is claimed is:

1. A testing apparatus for a power module, comprising:
a first socket board comprising a first withstand voltage test pin;
a second socket board comprising a second withstand voltage test pin and a direct current (DC) test pin;
a tester configured to:
generate a withstand voltage test signal,
transmit the withstand voltage test signal to the first withstand voltage test pin and the second withstand voltage test pin,
generate a DC test signal, and
transmit the DC test signal to the DC test pin; and
a relay configured to close and open an electrical connection between the tester and at least one of the first withstand voltage test pin, the second withstand voltage test pin, or the DC test pin.

2. The testing apparatus of claim 1, wherein the power module comprises (i) a lower substrate, (ii) an upper substrate disposed parallel to the lower substrate, and (iii) a semiconductor device disposed between the lower substrate and the upper substrate, and
wherein the first socket board comprises (i) an upper socket board configured to face the upper substrate and (ii) a lower socket board configured to face the lower substrate.

3. The testing apparatus of claim 2, wherein the first withstand voltage test pin of the upper socket board is configured to contact at least a portion of the upper substrate, and
wherein the first withstand voltage test pin of the lower socket board is configured to contact at least a portion of the lower substrate.

4. The testing apparatus of claim 3, wherein the power module further comprises a power lead and a signal lead, wherein at least a portion of each of the power lead and the signal lead is exposed to an outside of a housing of the power module, and
wherein the second withstand voltage test pin and the DC test pin are configured to be in contact with the power lead and the signal lead, respectively.

5. The testing apparatus of claim 4, wherein the second socket board comprises (i) a power socket board configured to contact the power lead and (ii) a signal socket board configured to contact the signal lead,
wherein the power socket board and the signal socket board are disposed on sides of the lower socket board, respectively.

6. The testing apparatus of claim 5, wherein the second withstand voltage test pin and the DC test pin of the power socket board are configured to contact at least a portion of the power lead, and
wherein the second withstand voltage test pin and the DC test pin of the signal socket board are configured to contact at least a portion of the signal lead.

7. The testing apparatus of claim 1, wherein the first socket board further comprises a first plate, and
wherein the first withstand voltage test pin is located at the first plate and configured to face the power module.

8. The testing apparatus of claim 1, wherein the second socket board further comprises a second plate,
wherein the DC test pin is one of a plurality of DC test pins that are located at the second plate and configured to face the power module, and
wherein the second withstand voltage test pin is located between the plurality of DC test pins and configured to face the power module.

9. The testing apparatus of claim 1, wherein the testing apparatus is configured to operate in a DC test mode or a withstand voltage test mode, and
wherein the relay is configured to switch the testing apparatus to the DC test mode or the withstand voltage test mode by controlling (i) an electrical connection between the DC test pin and the tester and (ii) an electrical connection between the tester and each of the first and second withstand voltage test pins.

10. The testing apparatus of claim 9, wherein the relay is configured to, in the DC test mode, electrically connect the tester to the DC test pin.

11. The testing apparatus of claim 9, wherein the relay is configured to, in the withstand voltage test mode, electrically connect the tester to the first withstand voltage test pin and the second withstand voltage test pin.

12. The testing apparatus of claim 9, wherein the relay is one of a plurality of relays that are connected (i) between the first withstand voltage test pin and the tester, (ii) between the second withstand voltage test pin and the tester, and (iii) between the DC test pin and the tester.

13. The testing apparatus of claim 12, wherein the plurality of relays comprise:
a first relay configured to be closed and connected to the DC test pin in the DC test mode, and
a second relay configured to be open and connected to the first withstand voltage test pin and the second withstand voltage test pin in the DC test mode.

14. The testing apparatus of claim 12, wherein the plurality of relays comprise:
a first relay configured to be closed and connected to the first withstand voltage test pin and the second withstand voltage test pin in the withstand voltage test mode; and
a second relay configured to be open and connected to the DC test pin in the withstand voltage test mode.

15. The testing apparatus of claim 12, wherein the plurality of relays comprise a cylinder relay.

16. A method of testing a power module, comprising:
mounting the power module on a testing apparatus;
performing a direct current (DC) test of the power module by operating the testing apparatus in a DC test mode; and
perform a withstand voltage test of the power module by operating the testing apparatus in a withstand voltage test mode,
wherein the testing apparatus comprises:
a first socket board comprising a first withstand voltage test pin,
a second socket board comprising a second withstand voltage test pin and a DC test pin,
a tester configured to generate a withstand voltage test signal and a DC test signal, and
a relay configured to switch an operating mode of the testing apparatus to the DC test mode or the withstand voltage test mode, and
wherein mounting the power module on the testing apparatus comprises contacting the power module with the first withstand voltage test pin, the second withstand voltage test pin, and the DC test pin.

17. The method of claim 16, wherein performing the DC test of the power module comprises electrically connecting, by the relay, the tester to the DC test pin.

18. The method of claim 16, wherein performing the withstand voltage test of the power module comprises electrically connecting, by the relay, the tester to the first withstand voltage test pin and the second withstand voltage test pin.

19. The method of claim 16, wherein the relay comprises a plurality of relays (i) connected between the first withstand voltage test pin and the tester, (ii) between the second withstand voltage test pin and the tester, and (iii) between the DC test pin and the tester.

20. The method of claim 19, wherein the plurality of relays comprise:
a first relay configured to be closed and connected to the DC test pin in the DC test mode;
a second relay configured to be open and connected to the first withstand voltage test pin and the second withstand voltage test pin in the DC test mode;
a third relay configured to be closed and connected to the first withstand voltage test pin and the second withstand voltage test pin in the withstand voltage test mode; and
a fourth relay configured to be open and connected to the DC test pin in the withstand voltage test mode.
